(19) United States
(12) Patent Application Publication
(10) Pub. No.: US 2012/0187802 A1
(43) Pub. Date: Jul. 26, 2012

(54) Nano Piezoelectric Actuator Energy Conversion Apparatus and Method of Making Same

(75) Inventors: Jeffery B. Moler, Sarasota, FL (US); Jeffrey M. Melzak, Beachwood, OH (US)

(73) Assignees: PARKER HANNIFIN CORPORATION, Cleveland, OH (US); VIKING AT, LLC, Sarasota, FL (US)

(21) Appl. No.: 13/499,018

(22) PCT Filed: Oct. 1, 2010
(86) PCT No.: PCT/US10/51142

§ 371 Date: Mar. 30, 2012

Related U.S. Application Data
(60) Provisional application No. 61/277,971, filed on Oct. 1, 2009.

(51) Int. Cl. H02N 2/18; H01L 41/22; H01L 41/083

(52) U.S. Cl. 310/339; 310/328; 29/25.35

(57) ABSTRACT

A nano piezoelectric actuator energy conversion apparatus fabricated from silicon comprising a mechanical amplifier comprising a fixed supporting member, a movable supporting member connected to compliant links attached to at least one actuating arm, and a piezoelectric stack affixed between the fixed supporting member and movable supporting member. Also disclosed is a method for fabricating a nano piezoelectric actuator from silicon and preloading the nano actuator with a piezoelectric stack.

### CROSS-REFERENCE TO RELATED APPLICATION

This application claims the benefit of U.S. Provisional Patent Application No. 61/277,971, filed Oct. 1, 2009, the contents of which are herein incorporated by reference. This application additionally claims the benefit of International Application No. PCT/US10 041,461, filed Jul. 9, 2010, the contents of which are herein incorporated by reference.

### BACKGROUND

The present disclosure relates to a small-scale piezo- or smart-material-actuator that can produce usable mechanical motion from electrical energy and can also serve to harvest electrical energy from mechanical motion. Actuators are known in the art. However, such devices are relatively large, and are not well-suited to applications requiring micro- or nano-sized components. The present disclosure corrects these shortcomings by providing more efficient actuators based on piezo- or smart-materials and methods of manufacturing said actuators in extremely small sizes.

This application hereby incorporates by reference U.S. Publication Number 2005/0231077 and U.S. Patents:

U.S. Pat. No. 6,717,332;

U.S. Pat. No. 6,548,938;

U.S. Pat. No. 6,737,788;

U.S. Pat. No. 6,836,056;

U.S. Pat. No. 6,879,087;

U.S. Pat. No. 6,759,790;

U.S. Pat. No. 7,132,781;

U.S. Pat. No. 7,126,259;

U.S. Pat. No. 6,870,305;

U.S. Pat. No. 6,975,061;

U.S. Pat. No. 7,368,856; and

U.S. Pat. No. 6,924,586.

### BRIEF DESCRIPTION OF THE DRAWINGS

Other features in the disclosure will become apparent from the attached drawings, which illustrate certain preferred embodiments of the apparatus of this disclosure, wherein

FIG. 1 shows a side view of a preferred embodiment of an actuator in accordance with the present disclosure;

FIG. 2 shows an isometric view of a preferred embodiment of an actuator in accordance with the present disclosure;

FIG. 3 shows an isometric view of a section of a piezoelectric stack suitable for use with an apparatus in accordance with the present disclosure;

FIG. 4 illustrates a multilayer piezoelectric stack suitable for use with an apparatus in accordance with the present disclosure;

FIG. 5a shows a side view of a preferred embodiment of a nano-actuator in accordance with the present disclosure using a single crystal piezoelectric material. FIG. 5b depicts the width of the nano-actuator depicted in FIG. 5a.

FIG. 6 is a flowchart depicting the steps in a process for fabricating a nano-actuator from silicon.

FIG. 7 shows a preferred embodiment of an actuator in accordance with the present disclosure in an alternate configuration.

FIG. 8 shows a method for preloading piezoelectric material in a nano-actuator in accordance with the present disclosure.

Similar reference characters refer to similar parts throughout the several views of the drawings.

### DETAILED DESCRIPTION

While the following describes preferred embodiments of the present disclosure, it is to be understood that this description is to be considered only as illustrative of the principles of the disclosure and is not to be limitative thereof, as numerous other variations, all within the scope of the disclosure, will readily occur to others. The term “adapted” shall mean sized, shaped, configured, dimensioned, oriented and arranged as appropriate.

International Application PCT/US10 041,461 discloses a small scale smart material actuator and energy harvesting apparatus, the disclosure of which is hereby incorporated by reference herein. This disclosure relates to a nano-sized smart material actuator and energy harvesting apparatus.

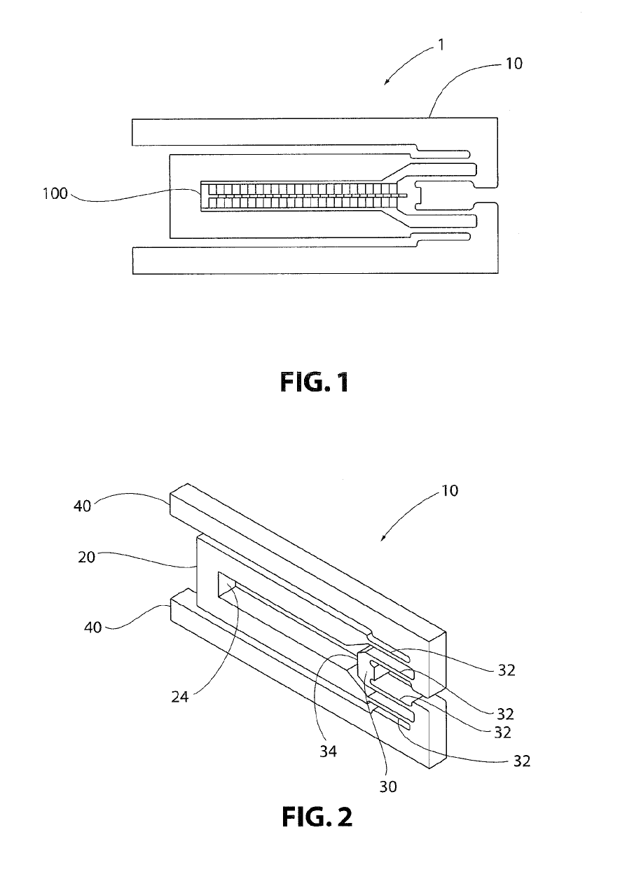

FIG. 1 depicts a small scale smart material actuator which may be fabricated in accordance with the present disclosure. As mentioned above, details on the actuator are found in PCT/US10 041,461. Briefly, the actuator 1 comprises a piezoelectric stack 100 housed in a unitary mechanical amplifier 10. See FIGS. 1 and 2. The mechanical amplifier 10 comprises a fixed supporting member 20 with a first mounting surface 24 and a movable supporting member 30 with a parallel and opposed second mounting surface 34. Preferably, the piezoelectric stack 100 is mounted between the first 24 and second mounting surfaces 34. The mechanical amplifier 10 also preferably may have at least one actuating arm 40 connected to at least one compliant mechanical link 32 connected to the movable supporting member 30. Thus, when a suitable electrical current is applied to the piezoelectric stack 100, the piezoelectric stack 100 expands, causing the amplifier 10 to mechanically move the actuating arm 40. Alternatively, when the actuating arm 40 is moved, the piezoelectric stack 100 is expanded or compressed, causing the piezoelectric stack 100 to generate electrical current. This electrical current can be stored in an energy storage device, such as a battery.

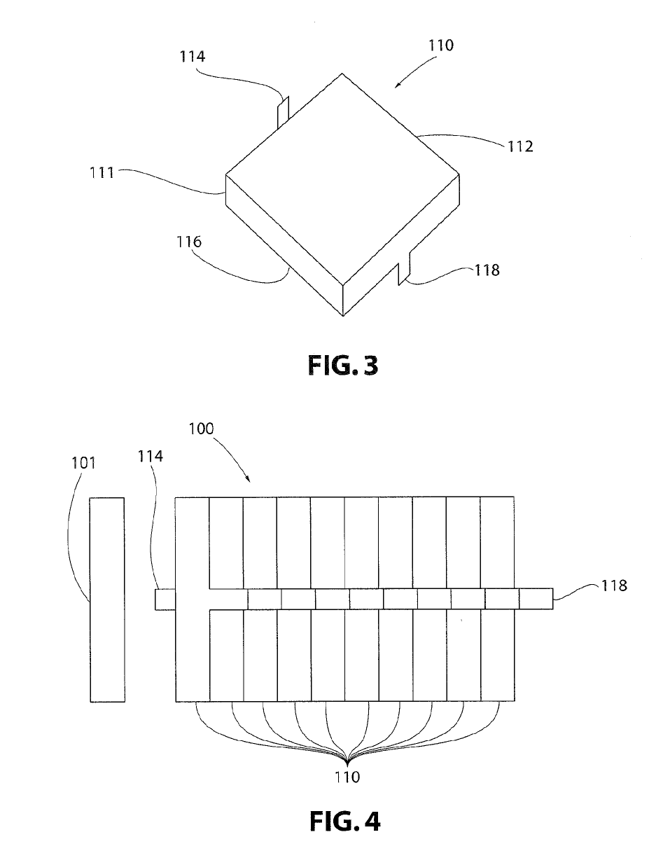

The piezoelectric stack 100 may be formed of one or more sections of piezoelectric material 111 with a positive electrode 112 and a negative electrode 116. See FIGS. 3 and 4. As discussed herein, the term piezoelectric material also includes so-called “smart materials,” sometimes created by doping known piezoelectric materials to change their electrical or mechanical properties.

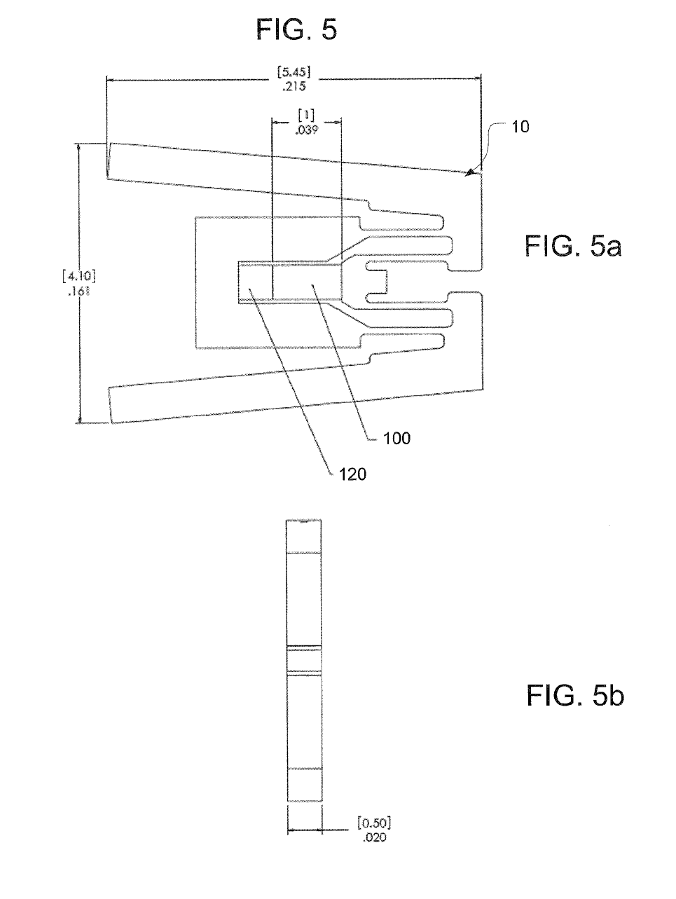

In a preferred embodiment, piezoelectric stack 100 is a single crystal piezoelectric material. See FIG. 5. FIG. 5 also depicts dimensions for a nano-actuator in accordance with the present disclosure. As shown, the actuator 1 is 5.45 mm long, and 4.10 mm tall. As shown in FIG. 5b, the actuator has a pitch of 0.5 mm.

Single crystal piezo material has much more mechanical output than multilayer co-fired piezo material. The drawback may be that single cell material is expensive. But for a nano sized actuator 1, as disclosed herein, the cost is a lesser impact because of the substantial performance improvements. As such, a single crystal piezo material is a preferred embodiment for the present disclosure.

Notably, because of its small size, a single crystal piezo material is highly efficient. Using an actuator 1 in accordance with the present disclosure, with a 0.4×0.5×1 mm long single crystal, we have observed the following theoretical performance:

| Free defelection | .78 | mm |
|---|---|---|
| Blocking force | .40N | |
| Maximum Von Mises Stress, free | 940 | MPa |
| Maximum Von Mises Stress, blocked | 1756 | MPa |

Using a 0.4×0.5×3 mm long single crystal, we have observed the following theoretical performance, demonstrating substantial improvements over standard PZT materials (see table below):

| | Single Crystal | PZT Material |
|---|---|---|
| Free defelection | 3.05 mm | .13 mm |
| Blocking force | .397N | .03N |

The combination of silicon with single crystal piezoelectric material results in extremely efficient energy conversion (either electrical energy into mechanical energy, or reverse operation of the actuator converting mechanical energy to electrical energy). Standard piezo cofired stacks can yield better efficiency in harvesting electrical energy from mechanical motion. The selection of material should be driven by the particular application.

It is beneficial to make such actuators in a very small scale. In accordance with the present disclosure, the actuator may be adapted to nano-sized components. The method of producing nano-sized actuators of the present disclosure comprises the steps of using silicon fabrication techniques, similar to those used to produce semiconductor devices, to produce actuators of substantially the proportions illustrated in FIG. 5, or other extremely small (nano) sizes, out of silicon, and then assembling the piezo stack or other smart material.

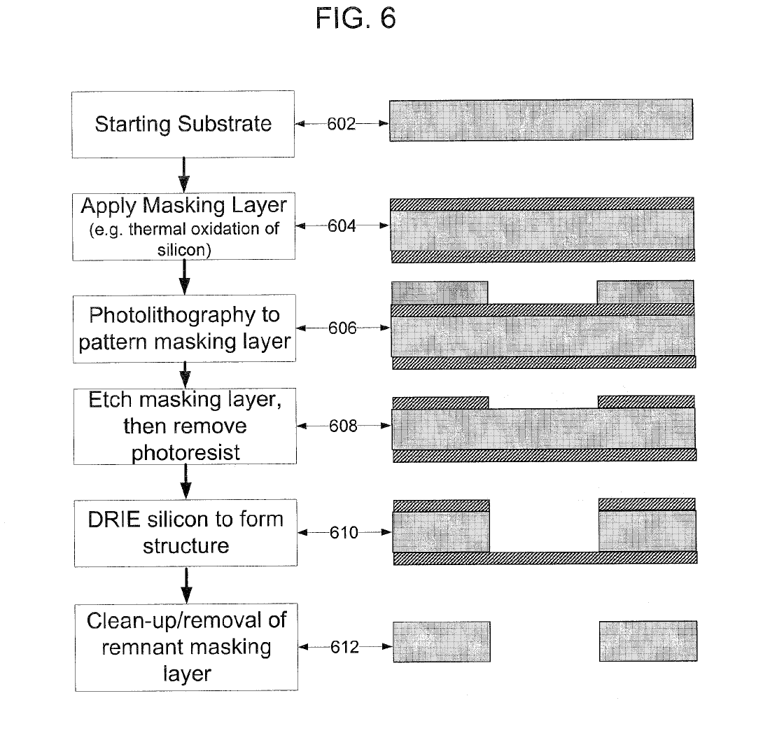

FIG. 6 discloses a silicon micromachining process which may be used for fabrication of a silicon version of an actuator (as disclosed herein. Silicon is a preferred material because it is readily available, has a Young's modulus that is comparable to stainless steel, and can be batch fabricated in large volumes for low unit cost with excellent dimensional control. The sketches adjacent the steps depicted in FIG. 6 represent cross-sectional views of one device in a wafer in accordance with the present disclosure.

The process begins at step 602 with a substrate, preferably a silicon wafer which is approximately 400 microns thick. At step 604, a masking layer is applied, e.g. through thermal oxidation of silicon. Next, a pattern masking layer is applied using photolithography at step 606. Then the photoresist is etched away at step 608. Next, at step 610, deep reactive ion etch (DRIE) silicon is used to form the structure of the actuator 1. Finally, the remnant masking layer is cleaned up and removed at step 612, producing a nano-actuator 1 in accordance with the present disclosure.

Additional steps may take place (not pictured) after the fabrication process discussed above. For example, metallic contact pads can be deposited on the actuator 1 using similar photolithographic process or “shadow mask” technique, as is known in the art. Wire bond lead wires can then be affixed to the contact pad.

The above process may also be altered to produce a thinner structure. Typical wafer thicknesses are 0.4 to 0.6 mm. If a thinner structure is desired, the starting substrate can either be a silicon on insulator (SOI) wafer with the top layer of silicon set to the desired structure thickness, or it can be a thinner silicon wafer that is mounted to a normal thickness handle wafer for support during fabrication. In both cases, there would be an extra process step to release the final structure.

The process can also be modified to increase conductivity of the material. Silicon is a semiconductor, and thus its electrical conductivity is a function of dopant level. Typically, the resistance of silicon is lower than that of most metals. If a low resistance structure is desired, the fabricated silicon structure could be subsequently coated conformally with a thin layer of metal (e.g., aluminum, gold, or other common metals) by physical vapor deposition, plating or similar processes.

It also may be desireable to incorporate strain gauge elements in or near the mechanical link 32 of the actuator 1. The strain gauge elements could be used to monitor the flexural stress(es) in the silicon structure during assembly and/or operation.

By using silicon fabricating techniques, an actuator 1 in accordance with the present disclosure can be made with extremely small dimensions. With such small sizes, nano-actuators built in accordance with the present disclosure have many useful applications.

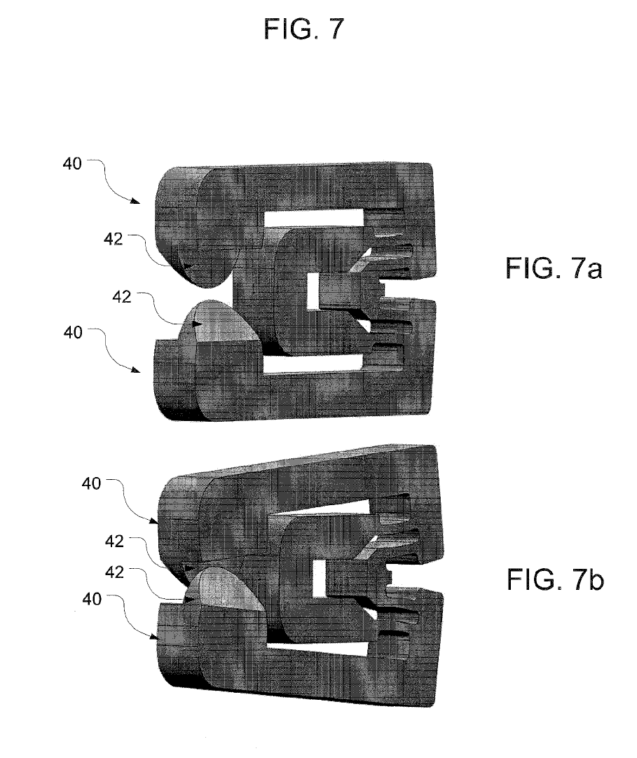

For example, and without limitation, blades 42 may be formed on actuating arms 40, thereby creating a cutting device useful in endoscopic surgical applications where a very small blade is needed to cut tissue, for example, to open a blocked artery or remove a small clot or tumor. See FIG. 7 (showing the actuator in an opened and closed position). Another example, also without limitation, would be to adapt actuator 1 to serve as an energy harvester by adapting actuating arms 40 to attach to a source of mechanical motion such as a muscle in an animal or human or to be flexed in a turbulent environment such as within a fluid stream inside an artery or a gas stream inside an air passage. In this way, the mechanical energy generated when stack 100 is repeatedly compressed and released by actuating arms 40 may be harvested by discharging the current into an electrical load such as an energy storage device. In this way, for example, excess mechanical energy could be converted into electrical energy that is then stored (i.e. in a rechargeable battery). That electrical energy could then be used to assist in, for example, driving a pacemaker, biosensor, or other bio-embedded, electrically driven device.

Piezoelectric stack 100 will benefit from being compressed by a predetermined amount, thereby creating a preload, such that the piezoelectric stack 100 remains compressed when no electrical potential is applied. Any such compressive force should be substantially evenly applied such that upon application of an electrical potential, the piezoelectric stack 100 expands without substantial angular flexing.

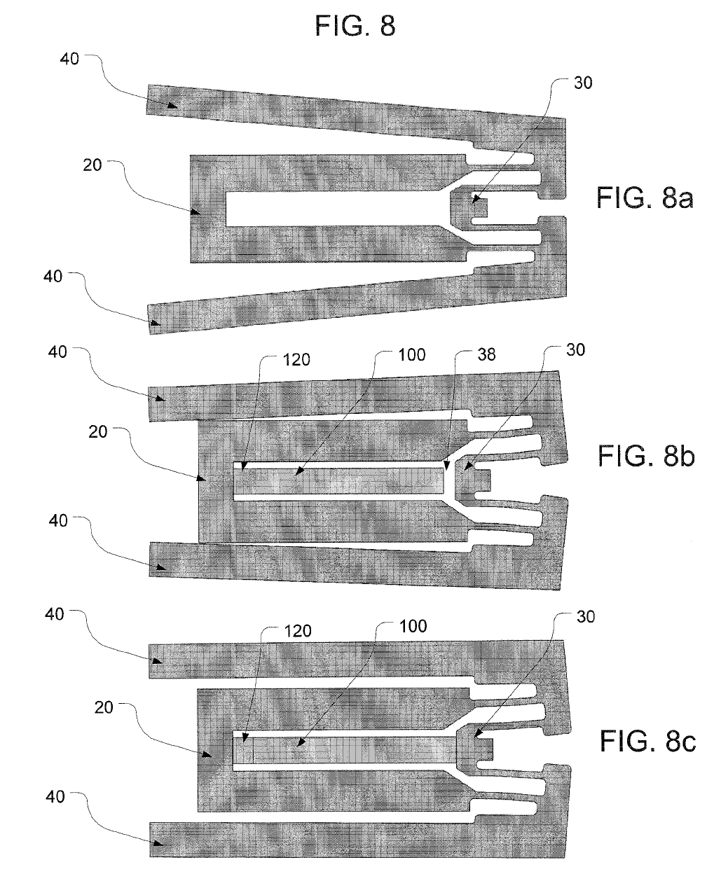

Because of the small size of actuators 1 in accordance with the present disclosure, additional steps may be taken to preload the piezoelectric stack 100 into the actuator 1. As depicted in FIG. 8a, the actuator begins in an unloaded state. The moveable supporting member 30 (also called the “anvil”) is then pulled away from the fixed supporting member 20. See FIG. 8b. The moveable supporting member 30 is pulled far enough away to create a gap 38 which is slightly larger than the appropriate preload level for the actuator 1.

Next, the piezoelectric material 100 and a stack plate 120 are inserted between the fixed supporting member 20 and the movable supporting member 30. Note that there still remains a small gap 38, leaving room to insert the piezoelectric material 100 and stack plate 120.

Finally, the movable supporting member 30 is released causing it to preload the piezoelectric material 100. See FIG. 8c. The compressive force will keep the piezoelectric material 100 housed within the actuator 1. Additionally, the force of mechanical links 32 cause the actuating arms to be positioned in a desired configuration when loaded. For instance, as shown in FIG. 8c, the actuating arms 40 are parallel to one another when the actuator 1 is loaded. Other configurations are possible, as would be understood by one of skill in the art.

Although this disclosure has been described in terms of certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure.

We claim:

1. A nano smart material actuator fabricated from silicon, the actuator comprising
a unitary mechanical amplifier fabricated from silicon comprising a fixed supporting member having a first mounting surface, an opposed movable supporting member having a second mounting surface, at least one actuating arm, and a mechanical link connecting the movable supporting member and the actuating arm, and a piezoelectric stack affixed between the first mounting surface and second mounting surface, wherein
the fixed supporting member is substantially rigid and the first mounting surface and the second mounting surface are substantially parallel such that upon application of an electrical potential to the piezoelectric stack, the piezoelectric stack expands substantially without movement of the fixed supporting member and substantially without angular movement of the piezoelectric stack;
the mechanical link comprises at least one compliant member linking the movable supporting member and the actuating arm whereby movement of the movable supporting member causes amplified movement of the actuating arm; and
the fixed supporting member, the movable supporting member and the mechanical link are adapted such that the piezoelectric stack is compressed by a predetermined amount such that the piezoelectric stack remains compressed when no electric potential is applied and the compressive force is substantially evenly applied to the piezoelectric stack such that upon application of an electric potential, the piezoelectric material expands without significant angular flexing,
whereby substantially upon application of an electric potential to the piezoelectric stack, the piezoelectric stack urges the second mounting surface away from the first mounting surface, thereby causing the compliant member of the mechanical link to flex, thereby moving the actuating arm such that motion of at least one part of the actuating arm is across a distance greater than the expansion of the piezoelectric stack.

2. A silicon nano actuator comprising:
a mechanical amplifier fabricated from silicon comprising at least one actuating arm; and
piezoelectric material housed in the amplifier such that mechanical movement of the actuating arm causes the material to generate electricity.

3. The apparatus of claim 2 wherein the amplifier is substantially 0.5 mm thick.

4. The apparatus of claim 2 wherein the amplifier is less than 0.75 mm thick.

5. The apparatus of claim 2 wherein the amplifier is less than 1 mm thick.

6. The apparatus of claim 2 wherein the amplifier is less than 2 mm thick.

7. The apparatus of claim 2 wherein the amplifier is substantially 7.5 mm long.

8. The apparatus of claim 2 wherein the amplifier is less than 20 mm long.

9. The apparatus of claim 2 wherein the piezoelectric material is a piezoelectric stack.

10. The apparatus of claim 9 wherein the piezoelectric stack is a co-fired ceramic piezo stack.

11. The apparatus of claim 9 wherein the piezoelectric stack comprises a stack of at least one section of single-crystal piezo material, such crystal having a positive electrode and a negative electrode.

12. The apparatus of claim 11 wherein the positive electrode and negative electrodes are printed on the sections of a single-crystal piezo material.

13. The apparatus of claim 12 wherein an adhesive causes the electrodes to adhere together.

14. The apparatus of claim 12 wherein a compressive force causes the electrodes to adhere together.

15. The apparatus of claim 2 wherein the piezoelectric material is a single crystal piezo material.

16. A method of making a nano actuator, the method comprising the following steps:
fabricating the actuator out of silicon wherein the actuator comprises a unitary mechanical amplifier comprising a fixed supporting member having a first mounting surface, an opposed movable supporting member having a second mounting surface, at least one actuating arm, and a mechanical link connecting the movable supporting member and the actuating arm;
moving the movable supporting member from a first position to a second position;
inserting a piezoelectric material between the fixed supporting member and movable supporting member; and
returning the movable supporting member from the second position so that the compressive force between the first supporting member and the movable supporting member holds the piezoelectric material in place.

17. The method of claim 16 wherein the supporting member is moved parallel to the actuating arm.

18. The method of claim 16 wherein the piezoelectric material is a single crystal piezo material.

19. The method of claim 16 wherein the piezoelectric material is a piezoelectric stack.

20. The method of claim 16 wherein the supporting member is moved using a tool.
